(19) United States
(12) Patent Application Publication
(10) Pub. No.: US 2025/0327843 A1
(43) Pub. Date: Oct. 23, 2025

(54) SIGNAL GENERATOR FOR GENERATING A RADIO FREQUENCY SIGNAL

(71) Applicant: Rohde & Schwarz GmbH & Co. KG, Muenchen (DE)

(72) Inventors: Matthias RUENGELER, Muenchen (DE); Michael KOENIG, Muenchen (DE)

(21) Appl. No.: 18/638,999

(22) Filed: Apr. 18, 2024

(51) Int. Cl. G01R 23/20; G01R 23/165; G01R 31/28

(52) U.S. Cl. CPC G01R 23/20; G01R 23/165; G01R 31/2822

(57) ABSTRACT

A signal generator includes a signal generator circuit configured to generate a two-tone radio frequency signal. First signal and second signals of the two-tone radio frequency signal are continuous wave signals spaced apart by a predetermined frequency. Each of the first signal and the second signal has a predetermined signal level. A measurement circuit is connected to an output path that starts at the signal generator circuit and ends at an output port of the signal generator. The measurement circuit is configured to measure a signal level of at least one intermodulation product of the two-tone radio frequency signal and to generate a measurement result. The signal generator further comprises a signal processing circuit configured to receive the measurement result from the measurement circuit and to control the signal generator circuit based on the measurement result such that a level of the at least one intermodulation product is reduced.

### FIELD OF THE DISCLOSURE

Embodiments of the present disclosure relate to a signal generator for generating a radio frequency signal, particularly for generating a two-tone radio frequency signal comprising a first continuous wave signal and a second continuous wave signal.

### BACKGROUND

In the state of the art, it is known to use two-tone radio frequency signals in two-tone testing of electronic devices for intermodulation distortion and particularly for determining a third-order intercept point (TOI) of a device. For generating the two-tone radio frequency signal, usually a signal generator is used that includes components like amplifiers and mixers that cause nonlinearities in the two-tone signal generated. However, for obtaining highly accurate measurement results, the two-tone signal should be free from those nonlinearities.

For obtaining a two-tone signal with reduced nonlinearities, it is known in the state of the art to use two signal generators which are set to two different frequencies. The signal generators are associated with corresponding signal paths and an external power splitter. This solution however requires high efforts with regard to the hardware to be used.

Alternatively, it is known to measure the third-order intercept point (TOI) of the signal generator for every level and every frequency while optimizing a relative phase of the tones of the two-tone signal generated. The respective measurement can be performed by a spectrum analyzer.

Accordingly, there is a need for signal generators that can provide a two-tone radio frequency signal of high quality, namely without nonlinearities or at least reduced nonlinearities, in a time-efficient and user-friendly way.

### SUMMARY

The following summary of the present disclosure is intended to introduce different concepts in a simplified form that are described in further detail in the detailed description provided below. This summary is neither intended to denote essential features of the present disclosure nor shall this summary be used as an aid in determining the scope of the claimed subject matter.

The present disclosure provides a signal generator for generating a radio frequency signal. In an embodiment, the signal generator comprises a signal generator circuit configured to generate a two-tone radio frequency signal. The two-tone radio frequency signal comprises a first signal and a second signal. The first signal and the second signal are continuous wave (CW) signals spaced apart by a predetermined frequency. Each of the first signal and the second signal has a predetermined signal level. The signal generator further comprises a measurement circuit connected to an output path that starts at the signal generator circuit and ends at an output port of the signal generator. The measurement circuit is configured to measure a signal level of at least one intermodulation product of the two-tone radio frequency signal and to generate a measurement result. The signal generator further comprises a signal processing circuit connected to the measurement circuit. The signal processing circuit is configured to receive the measurement result from the measurement circuit and to control the signal generator circuit based on the measurement result such that a level of the at least one intermodulation product is reduced.

Hence, nonlinearities of the two-tone signal can be mitigated or eliminated, leading to a two-tone signal of high quality, namely without nonlinearities or at least reduced nonlinearities. Thus, accurate measurement results can be ensured when the two-tone signal is used for two-tone testing of electronic devices and particularly for determining a third-order intercept point (TOI) of a device under test.

Moreover, the two-tone signal of high quality can be provided quickly, since the signal generation is controlled by the signal processing circuit. It is thus not necessary for a user to measure intermodulation products or TOI values manually and to experiment with different relative phases of the tones. Therefore, the efficiency of performing two-tone testing can be increased substantially.

In an embodiment, the signal generator circuit and the measurement circuit are arranged within the signal generator (device). Hence, the first signal and the second signal can be generated by one single signal generator (device), namely a device having a housing that encompasses the signal generator circuit, the measurement circuit and the signal processing circuit. The two-tone signal can thus be provided in a user-friendly way, since it is provided directly at the output port of the signal generator. It is therefore not required to combine signals from different sources, i.e. from different signal generators or output ports. Setups for two-tone testing can thus be simplified and the corresponding costs can be reduced.

Controlling the signal generator circuit may be understood as sending a control signal to the signal generator circuit so that the signal generator circuit performs the intended operation, e.g. generating the two-tone radio frequency signal.

Generally, the measurement circuit is configured to perform the measurement, namely to measure the signal level of the at least one intermodulation product of the two-tone radio frequency signal and to generate the measurement result, before the two-tone radio frequency signal is outputted via the output port of the signal generator. In other words, the measurement circuit intercepts the output path that starts at the signal generator circuit and ends at the output port of the signal generator.

In an embodiment, the signal generator circuit may be configured to adjust a signal level of the first signal and a signal level of the second signal independently from each other. In particular, the signal generator circuit is configured to adjust the signal levels independently from each other in case the signal levels of the first signal and the second signal are different, for example if they have different values measured in dBm (decibel-milliwatts).

In an embodiment, the signal generator circuit may be configured to adjust a signal level of the first signal and a signal level of the second signal equally. In particular, the signal generator circuit is configured to adjust the signal levels equally in case the signal levels of the first signal and the second signal are the same, for example if they have the same value measured in dBm.

In an embodiment, the signal processing circuit may be configured to control the signal generator circuit such that the signal generator circuit adjusts a phase difference between the first signal and the second signal. As a result of the phase adjustment, a signal level of the intermodulation product can be reduced. Thus, a quality of the two-tone radio frequency signal can be improved. Adjusting the phase difference is particularly to be understood as increasing or decreasing the phase difference, namely the relative phase of the first signal and the second signal.

In an embodiment, the signal generator circuit may be configured to increase or decrease the phase difference for as long as the signal level of the intermodulation product is reduced further as a result of the adjustment. In particular, if the signal level of the intermodulation product starts rising again as a result of the adjustment of the phase difference, the adjustment is stopped and an appropriate adjustment in the opposite direction (e.g. a decrease instead of an increase) may be performed so as to reach the (local) minimum regarding the signal level of the intermodulation product.

In an embodiment, increasing or decreasing the phase difference may be done in a step-wise manner.

In an embodiment, the signal processing circuit may be configured to control the signal generator circuit such that the signal generator circuit generates at least one additional continuous wave signal, wherein at least one of an amplitude and a phase of the additional continuous wave signal is selected such that the level of the at least one intermodulation product is reduced. A quality of the two-tone radio frequency signal can thus be improved further, as the contribution of the intermodulation product is reduced.

The additional continuous wave signal can be understood as a counter signal. In an embodiment, the additional continuous wave signal may have an opposite phase than the intermodulation product. The required phase may be obtained from a phase measurement of the intermodulation product or by an estimation.

In an embodiment, the signal processing circuit may be configured to control the signal generator circuit such that the signal generator circuit generates at least a third signal and a fourth signal, wherein the third signal and the fourth signal are continuous wave signals. In particular, the third and the fourth signals are counter signals for reducing or eliminating intermodulation products, e.g. a first intermodulation product and a second intermodulation product. In other words, the third signal may be used for reducing or eliminating the first intermodulation product, whereas the fourth signal may be used for reducing or eliminating the second intermodulation product.

In an embodiment, a phase of the third signal may be selected such that a level of a first intermodulation product is reduced and/or a phase of the fourth signal may be selected such that a level of a second intermodulation product is reduced. Thus, by targeting individual intermodulation products specifically with a respective counter signal, two-tone radio frequency signal of a particularly high quality can be provided, namely the two-tone signal without nonlinearities or at least reduced nonlinearities.

In an embodiment, a phase of the third signal may be opposite to a phase of the first intermodulation product and/or a phase of the fourth signal may be opposite to a phase of the second intermodulation product. A substantial reduction or even elimination of the respective intermodulation product can thus be achieved, resulting in the two-tone signal of high quality.

In an embodiment, the signal processing circuit may be configured to control the signal generator circuit such that a signal level of the third signal is approximately the same as a signal level of the first intermodulation product and/or that a signal level of the fourth signal is approximately the same as a signal level of the second intermodulation product. In this regard, the term approximately may be understood as the difference between the signal levels being smaller than a threshold, for example a predetermined threshold.

In an embodiment, the signal level of the third signal and/or the signal level of the fourth signal may be changed iteratively. In an embodiment, the signal level of the respective intermodulation product is measured and it is monitored if the intermodulation product is eliminated or at least reduced (further). Hence, an automatic reduction or elimination of intermodulation products can be enabled without additional user involvement. A two-tone radio frequency signal of high quality can thus be provided in an efficient and user-friendly way.

In an embodiment, the measurement circuit may be configured to measure a phase of the at least one intermodulation product of the two-tone radio frequency signal, for example of the first intermodulation product and the second intermodulation product. Hence, phase information that can be used for reducing or eliminating the at least one intermodulation product is be obtained.

In an embodiment, the measurement circuit may be configured to measure a signal level of the first signal and a signal level of the second signal. The information about the signal levels can likewise be used for reducing or eliminating the at least one intermodulation product.

Generally, a phase information could be obtained from a phase measurement of the intermodulation product or by an estimation. The signal level of the intermodulation product can be measured by the measurement circuit. The frequency of the intermodulation product is known and is based on the frequency of the first signal and the second signal. The phase of the third signal and/or the phase of the fourth signal are/is changed while the signal level of the intermodulation product is continuously measured.

In an embodiment, the signal generator circuit may comprise a first continuous wave generator and a second continuous wave generator which are configured to generate the first signal and the second signal, respectively. Alternatively, the signal generator circuit may comprise a digital-to-analog converter configured to generate the first signal and the second signal. As another alternative, the signal generator circuit may comprise a first digital-to-analog converter and a second digital-to-analog converter which are configured to generate the first signal and the second signal, respectively.

Generally, the signal generator circuit may comprise at least one additional continuous wave generator. Hence, an additional continuous wave signal can be generated. For example, the signal generator may comprise a third continuous wave generator and a fourth continuous wave generator for generating a third continuous wave signal and a fourth continuous wave signal, respectively. A signal generator can thus be provided that is able to create counter signal(s) for reducing or eliminating intermodulation product(s). A two-tone radio frequency signal of a particularly high quality can thus be achieved in a user-friendly and time-efficient way.

In case the first continuous wave generator and the second continuous wave generator are provided, an output of the first continuous wave generator and an output of the second continuous wave generator may be combined such that the first signal and the second signal are combined to a combined signal. The combined signal may be processed by an amplifier, a mixer, a filter, and/or an attenuator.

In case the first continuous wave generator and the second continuous wave generator are provided, an output of the first continuous wave generator may be connected to a first amplifier, a first mixer, a first filter, and/or a first attenuator such that the first signal is processed by the first amplifier, the first mixer, the first filter, and/or the first attenuator. An output of the second continuous wave generator may be connected to a second amplifier, a second mixer, a second filter, and/or a second attenuator such that the second signal is processed by the second amplifier, the second mixer, the second filter, and/or the second attenuator.

The signals outputted by the continuous wave generators can thus be processed separately and a quality of the two-tone radio frequency signal can be further improved. As one example, the respective signal level of the first signal and the second signal can be adjusted individually via separate amplifiers.

In case the digital-to-analog converter is provided that generates the first signal and the second signal, an output of the digital-to-analog converter may be connected to an amplifier, a mixer, a filter, and/or an attenuator such that the first signal and the second signal generated by the digital-to analog-converter are processed by the amplifier, the mixer, the filter, and/or the attenuator.

In case the first digital-to-analog converter and the second digital-to-analog converter are provided, an output of the first digital-to-analog converter may be connected to a first amplifier, a first mixer, a first filter, and/or a first attenuator such that the first signal is processed by the first amplifier, the first mixer, the first filter, and/or the first attenuator. An output of the second digital-to-analog converter may be connected to a second amplifier, a second mixer, a second filter, and/or a second attenuator such that the second signal is processed by the second amplifier, the second mixer, the second filter, and/or the second attenuator.

As in the case of the two continuous wave generators mentioned above, the signals outputted by the digital-to-analog converters can thus be processed separately and a quality of the two-tone radio frequency signal can be further improved.

In an embodiment, the signal processing circuit may be configured to control an amplifier and/or an attenuator. In particular, at least one amplifier and/or at least one attenuator of the signal generator circuit are/is controlled. The control may be based on a signal level of an intermodulation product measured by the measurement circuit. In particular, the amplifier and/or the attenuator is controlled such that the intermodulation product is eliminated.

In an embodiment, the measurement circuit may comprise a frequency-selective power meter. Alternatively or additionally, the measurement circuit may comprise a mixer, a filter, an attenuator, and/or an analog-to-digital converter. The measurement circuit may comprise a comb mixing circuit and an analog-to-digital converter, wherein the comb mixing circuit is configured to mix down the first signal and the second signal as well as the at least one intermodulation product. As an example, the comb mixing circuit may be configured at least partly as the calibration unit described in patent U.S. Pat. No. 11,346,869 B2, which is hereby incorporated by reference.

In an embodiment, the signal generator may comprise a user interface, wherein the signal processing circuit may be configured to receive a user input via the user interface. The signal processing circuit may be configured to start or stop controlling the signal generator circuit based on the measurement result.

In an embodiment, the user interface is located at a housing of the signal generator (device), namely the housing that encompasses the signal generator circuit, the measurement circuit and the signal processing circuit.

In an embodiment, the, the signal generator circuit may be controlled as long as the third-order intercept point (TOI) is improved, for example increased. Control of the signal processing circuit may be stopped as soon as the TOI stops showing improvement, for example stops increasing. Hence, the signal processing circuit can control the signal generator circuit in a particularly efficient manner whilst providing good results. For many use cases, high efficiency is beneficial and a further improvement or optimization of the TOI is not required.

In an embodiment, the signal generator may comprise a user interface, wherein the signal processing circuit may be configured to display a measured TOI on the user interface. The TOI may be displayed both while the control of the signal generator circuit by the signal processing circuit is activated and while it is deactivated. Hence, a user may observe if and how the TOI improves after activation of the control.

In an embodiment, the signal generator may comprise a switchable attenuator provided upstream of the measurement circuit, wherein the signal processing circuit may be configured to control the switchable attenuator. The switchable attenuator may be controlled such that a measured TOI is improved. In particular, the signal processing circuit is configured to enable or disable the switchable attenuator.

In an embodiment, an attenuation factor (e.g. in dB) may be set via the signal processing circuit. The switchable attenuator may comprise various attenuator stages that can be activated independently from each other. Hence, a more finely graduated control of the switchable attenuator is enabled and further improvements to the measured TOI can be made.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 is a schematic view of a signal generator according to an embodiment of the present disclosure;

FIG. 2 is a schematic diagram illustrating a two-tone signal comprising two continuous wave signals and intermodulation products;

FIG. 3 is a schematic view of a signal generator circuit used in a signal generator according to a first embodiment of the present disclosure;

FIG. 4 is a schematic view of a signal generator circuit used in a signal generator according to a second embodiment of the present disclosure; and

FIG. 5 is a schematic view of a signal generator circuit used in a signal generator according to a third embodiment of the present disclosure.

FIG. 6 is a schematic view of a signal generator circuit used in a signal generator according to a fourth embodiment of the present disclosure.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

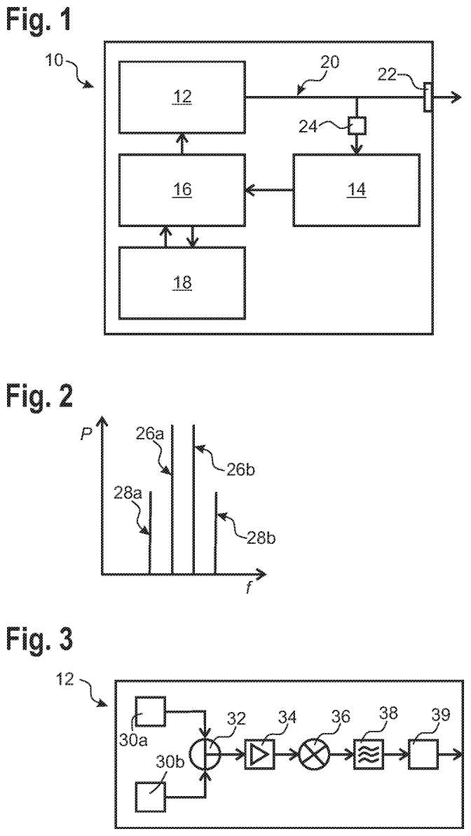

FIG. 1 is a schematic view of a signal generator (device) 10 for generating a radio frequency signal according to an embodiment of the present disclosure. The signal generator 10 comprises a signal generator circuit 12 configured to generate a two-tone radio frequency signal, for example as illustrated in FIG. 2.

As shown, the two-tone radio frequency signal comprises a first signal and a second signal. The first signal and the second signal are continuous wave signals 26a, 26b spaced apart by a predetermined frequency. As one specific example, the continuous wave signals 26a, 26b may have a frequency of approximately 44 GHz and be spaced apart by a predetermined frequency of 1 MHz.

In addition, intermodulation products 28a, 28b of the two-tone radio frequency signal are shown in FIG. 2. The intermodulation products 28a, 28b may have a frequency of 2 fin, 1 fin,2 and 2 fin,2 fin, 1, respectively. Therein, fin, 1 and fin,2 are the frequencies of the continuous wave signals 26a, 26b (i.e. the first and the second signal) of the two-tone radio frequency signal.

Each of the first signal 26a and the second signal 26b has a predetermined signal level. The signal generator circuit 12 may be configured to adjust a signal level of the first signal 26a and a signal level of the second signal 26b equally or independently from each other. As one specific example, the continuous wave signals 26a, 26b, for example the first signal 26a and the second signal 26b, may have a signal level of 1 dBm (decibel milliwatts).

The signal generator 10 further comprises a measurement circuit 14 connected to an output path 20 that starts at the signal generator circuit 12 and ends at an output port 22 of the signal generator 10. The measurement circuit 14 intercepts the output path 20 prior to the output port 22 such that the two-tone radio frequency signal is processed by the measurement circuit 14 before being outputted via the output port 22. The measurement circuit 14 is configured to inter alia measure a signal level of at least one intermodulation product 28a, 28b of the two-tone radio frequency signal and to generate a measurement result.

In an embodiment, the measurement circuit 14 may comprise a frequency-selective power meter. Alternatively or additionally, the measurement circuit 14 may comprise a mixer, a filter, an attenuator, and/or an analog-to-digital converter (ADC). As another alternative or additionally, the measurement circuit 14 may comprise a comb mixing circuit and an ADC. In an embodiment, the comb mixing circuit is configured to mix down the first signal and the second signal as well as the at least one intermodulation product 28a, 28b. Embodiments where the measurement circuit 14 comprises an ADC enable a power measurement in digital hardware.

In an embodiment, the signal generator 10 further comprises a signal processing circuit 16 connected to the measurement circuit 14. The signal processing circuit 16 is configured to receive the measurement result from the measurement circuit 14 and to control the signal generator circuit 12 based on the measurement result such that a level of the at least one intermodulation product 28a, 28b is reduced.

In an embodiment, the signal processing circuit 16 may be configured to start or stop controlling the signal generator circuit 12 based on the measurement result. Further, the signal processing circuit 16 may be configured to control the signal generator circuit 12 such that the signal generator circuit 12 adjusts a phase difference between the first signal 26a and the second signal 26b. As a result of the phase adjustment, a signal level of the intermodulation products 28a, 28b can be reduced.

In an embodiment, the signal processing circuit 16 may be configured to control the signal generator circuit 12 such that the signal generator circuit 12 generates at least one additional continuous wave signal, wherein an amplitude and/or a phase of the additional continuous wave signal is selected such that the level of the at least one intermodulation product 28a, 28b is reduced, for instance the first intermodulation product 28a and/or the second intermodulation product 28b. The additional continuous wave signal can be understood as a counter signal. In particular, the additional continuous wave signal may have an opposite phase than the respective intermodulation product 28a, 28b.

In embodiments, the signal processing circuit 16 may be configured to control the signal generator circuit 12 such that the signal generator circuit 12 generates at least a third signal and a fourth signal, wherein the third signal and the fourth signal are continuous wave signals.

A phase of the third signal may be selected such that a level of the first intermodulation product 28a is reduced. In an embodiment, a phase of the third signal may be opposite to a phase of the first intermodulation product 28a. Likewise, a phase of the fourth signal may be selected such that a level of the second intermodulation product 28b is reduced. In an embodiment, a phase of the fourth signal may be opposite to a phase of the second intermodulation product 28b.

In an embodiment, the signal processing circuit 16 may be configured to control the signal generator circuit 12 such that a signal level of the third signal is approximately the same as a signal level of the first intermodulation product 28a. Additionally or alternatively, the signal processing circuit 16 may be configured to control the signal generator circuit 12 such that a signal level of the fourth signal is approximately the same as a signal level of the second intermodulation product 28b. In this regard, the term approximately is particularly to be understood as the difference between the signal levels being smaller than a predetermined threshold.

In an embodiment, the measurement circuit 14 may be configured to measure a phase of the at least one intermodulation product 28a, 28b of the two-tone radio frequency signal. Additionally or alternatively, the measurement circuit 14 may be configured to measure a signal level of the first signal 26a and the second signal 26b.

In an embodiment, the signal generator 10 may further comprise a user interface 18, wherein the signal processing circuit 16 may be configured to receive a user input via the user interface 18. The user interface 18 may comprise a graphical user interface (GUI). The signal processing circuit 16 may be configured to display a measured third-order intercept point (TOI) on the user interface 18. The TOI may be displayed both while the control of the signal generator circuit 12 by the signal processing circuit 16 is activated and while it is deactivated. Hence, a user may observe if and how the TOI improves after activation of the control.

In addition or as an alternative to the user interface 18, the signal generator 10 may comprise an application programming interface (API). Communication with a computer program can thus be enabled. Hence, for example measurement results may be transmitted to a computer program for further processing and/or display.

In an embodiment, the signal generator 10 may further comprise a switchable attenuator 24 provided upstream of the measurement circuit 14, wherein the signal processing circuit 16 may be configured to control the switchable attenuator 24. In an embodiment, the signal processing circuit 16 is configured to enable or disable the switchable attenuator 24. The switchable attenuator 24 may be controlled such that a measured TOI is improved.

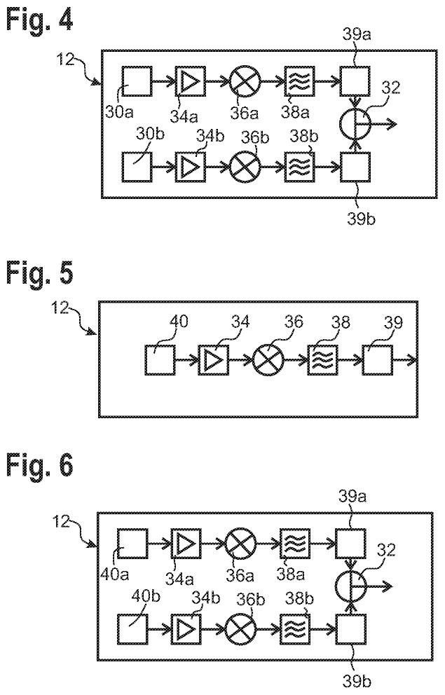

In some embodiment, for example as shown in FIGS. 3 and 4, the signal generator circuit 12 may comprise a first continuous wave generator 30a and a second continuous wave generator 30b which are configured to generate the first signal 26a and the second signal 26b, respectively.

As illustrated in FIG. 3, an output of the first continuous wave generator 30a and an output of the second continuous wave generator 30b may be combined such that the first signal 26a and the second signal 26b are combined to a combined signal, for example via a combiner 32 (power combiner). The combined signal may be processed by at least one of an amplifier 34, a mixer 36, a filter 38, and/or an attenuator 39.

In another configuration, for example as shown in FIG. 4, an output of the first continuous wave generator 30a may be connected to a first amplifier 34a, a first mixer 36a, a first filter 38a, and/or a first attenuator 39a such that the first signal 26a is processed by the first amplifier 34a, the first mixer 36a, the first filter 38a, and/or the first attenuator 39a.

Likewise, an output of the second continuous wave generator 30b may be connected to a second amplifier 34b, a second mixer 36b, a second filter 38b, and/or a second attenuator 39b such that the second signal 26b is processed by the second amplifier 34b, the second mixer 36b, the second filter 38b, and/or the second attenuator 39b.

The signals 26a, 26b outputted by the continuous wave generators 30a, 30b can thus be processed separately and a quality of the two-tone radio frequency signal can be further improved. After having been processed, the first signal 26a and the second signal 26b may be combined, for example via a combiner 32 (power combiner).

Alternatively, for example as shown in FIG. 5, the signal generator circuit 12 may comprise a digital-to-analog converter 40 configured to generate the first signal 26a and the second signal 26b. An output of the digital-to analog-converter 40 may be connected to an amplifier 34, a mixer 36, a filter 38, and/or an attenuator 39 such that the first signal 26a and the second signal 26b generated by the digital-to analog-converter 40 are processed by the amplifier 34, the mixer 36, the filter 38, and/or the attenuator 39.

As another alternative, for example as shown in FIG. 6, the signal generator circuit 12 may comprise a first digital-to-analog converter 40a and a second digital-to-analog converter 40b which are configured to generate the first signal 26a and the second signal 26b, respectively. An output of the first digital-to-analog converter 40a may be connected to a first amplifier 34a, a first mixer 36a, a first filter 38a, and/or a first attenuator 39a such that the first signal 26a is processed by the first amplifier 34a, the first mixer 36a, the first filter 38a, and/or the first attenuator 39a.

Likewise, an output of the second digital-to-analog converter 40b may be connected to a second amplifier 34b, a second mixer 36b, a second filter 38b, and/or a second attenuator 39b such that the second signal 26b is processed by the second amplifier 34b, the second mixer 36b, the second filter 38b, and/or the second attenuator 39b. The signals 26a, 26b outputted by the digital-to-analog generators 40a, 40b can thus be processed separately (as in the case of the two continuous wave generators 30a, 30b described above).

After having been processed, the first signal 26a and the second signal 26b may be combined, for example via a combiner 32 (power combiner).

In an embodiment, the signal processing circuit 16 may be configured to control the amplifier 34, 34a, 34b and/or the attenuator 24, 39, 39a, 39b, for example the amplifier 34, 34a, 34b and/or the attenuator 39, 39a, 39b of the signal generator circuit 12. The control may be based on a signal level of an intermodulation product 28a, 28b measured by the measurement circuit 14. In particular, the amplifier 34, 34a, 34b and/or the attenuator 39, 39a, 39b is controlled such that the intermodulation product 28a,28b is eliminated.

Certain embodiments disclosed herein include systems, apparatus, modules, units, devices, components, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be use synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a digital signal processor (DSP), an application-specific integrated circuit (ASIC), a field programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

For example, the functionality described herein can be implemented by special purpose hardware-based computer systems or circuits, etc., or combinations of special purpose hardware and computer instructions. Each of these special purpose hardware-based computer systems or circuits, etc., or combinations of special purpose hardware circuits and computer instructions form specifically configured circuits, machines, apparatus, devices, etc., capable of implementing the functionality described herein.

Of course, in an embodiment, two or more of these components, or parts thereof, can be integrated or share hardware and/or software, circuitry, etc. In an embodiments, these components, or parts thereof, may be grouped in a single location or distributed over a wide area. In circumstances where the components are distributed, the components are accessible to each other via communication links.

In an embodiment, one or more of the components referenced above include circuitry programmed to carry out one or more steps of any of the methods disclosed herein. In an embodiments, one or more computer-readable media associated with or accessible by such circuitry contains computer readable instructions embodied thereon that, when executed by such circuitry, cause the component or circuity to perform one or more steps of any of the methods disclosed herein.

In an embodiment, the computer readable instructions includes applications, programs, program modules, scripts, source code, program code, object code, byte code, compiled code, interpreted code, machine code, executable instructions, and/or the like (also referred to herein as executable instructions, instructions for execution, program code, computer program instructions, and/or similar terms used herein interchangeably).

In an embodiment, computer-readable media is any medium that stores computer readable instructions, or other information non-transitorily and is directly or indirectly accessible to a computing device, such as processor circuitry, etc., or other circuity disclosed herein etc. In other words, a computer-readable medium is a non-transitory memory at which one or more computing devices can access instructions, codes, data, or other information. As a non-limiting example, a computer-readable medium may include a volatile random access memory (RAM), a persistent data store such as a hard disk drive or a solid-state drive, or a combination thereof. In an embodiment, memory can be integrated with a processor, separate from a processor, or external to a computing system.

Accordingly, blocks of the block diagrams and/or flowchart illustrations support various combinations for performing the specified functions, combinations of operations for performing the specified functions and program instructions for performing the specified functions. These computer program instructions may be loaded onto one or more computer or computing devices, such as special purpose computer(s) or computing device(s) or other programmable data processing apparatus(es) to produce a specifically-configured machine, such that the instructions which execute on one or more computer or computing devices or other programmable data processing apparatus implement the functions specified in the flowchart block or blocks and/or carry out the methods described herein. Again, it should also be understood that each block of the block diagrams and flowchart illustrations, and combinations of blocks in the block diagrams and/or flowchart illustrations, or portions thereof, could be implemented by special purpose hardware-based computer systems or circuits, etc., that perform the specified functions or operations, or combinations of special purpose hardware and computer instructions.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure.

In the detailed description herein, references to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. In addition, when a particular feature, structure, or characteristic is described in connection with an embodiment, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

1. A signal generator for generating a radio frequency signal, wherein the signal generator comprises:
a signal generator circuit configured to generate a two-tone radio frequency signal, wherein the two-tone radio frequency signal comprises a first signal and a second signal, wherein the first signal and the second signal are continuous wave signals spaced apart by a predetermined frequency, and wherein each of the first signal and the second signal has a predetermined signal level;
a measurement circuit connected to an output path that starts at the signal generator circuit and ends at an output port of the signal generator, wherein the measurement circuit is configured to measure a signal level of at least one intermodulation product of the two-tone radio frequency signal and to generate a measurement result; and
a signal processing circuit connected to the measurement circuit, wherein the signal processing circuit is configured to receive the measurement result from the measurement circuit and to control the signal generator circuit based on the measurement result such that a level of the at least one intermodulation product is reduced.

2. The signal generator according to claim 1, wherein the signal generator circuit is configured to adjust a signal level of the first signal and a signal level of the second signal independently from each other.

3. The signal generator according to claim 1, wherein the signal generator circuit is configured to adjust a signal level of the first signal and a signal level of the second signal equally.

4. The signal generator according to claim 1, wherein the signal processing circuit is configured to control the signal generator circuit such that the signal generator circuit adjusts a phase difference between the first signal and the second signal.

5. The signal generator according to claim 1, wherein the signal processing circuit is configured to control the signal generator circuit such that the signal generator circuit generates at least one additional continuous wave signal, wherein an amplitude and/or a phase of the additional continuous wave signal is selected such that the level of the at least one intermodulation product is reduced.

6. The signal generator according to claim 1, wherein the signal processing circuit is configured to control the signal generator circuit such that the signal generator circuit generates at least a third signal and a fourth signal, wherein the third signal and the fourth signal are continuous wave signals.

7. The signal generator according to claim 6, wherein a phase of the third signal is selected such that a level of a first intermodulation product is reduced, and/or wherein a phase of the fourth signal is selected such that a level of a second intermodulation product is reduced.

8. The signal generator according to claim 6, wherein a phase of the third signal is opposite to a phase of the first intermodulation product and/or wherein a phase of the fourth signal is opposite to a phase of the second intermodulation product.

9. The signal generator according to claim 6, wherein the signal processing circuit is configured to control the signal generator circuit such that a signal level of the third signal is approximately the same as a signal level of the first intermodulation product and/or that a signal level of the fourth signal is approximately the same as a signal level of the second intermodulation product.

10. The signal generator according to claim 1, wherein the measurement circuit is configured to measure a phase of the at least one intermodulation product of the two-tone radio frequency signal and/or wherein the measurement circuit is configured to measure a signal level of the first signal and the second signal.

11. The signal generator according to claim 1, wherein the signal generator circuit comprises a first continuous wave generator and a second continuous wave generator which are configured to generate the first signal and the second signal, respectively, or wherein the signal generator circuit comprises a digital-to-analog converter configured to generate the first signal and the second signal, or wherein the signal generator circuit comprises a first digital-to-analog converter and a second digital-to-analog converter which are configured to generate the first signal and the second signal, respectively.

12. The signal generator according to claim 11, wherein, in case the first continuous wave generator and the second continuous wave generator are provided, an output of the first continuous wave generator and an output of the second continuous wave generator are combined such that the first signal and the second signal are combined to a combined signal, and wherein the combined signal is processed by at least one of an amplifier, a mixer, a filter, and an attenuator.

13. The signal generator according to claim 11, wherein, in case the first continuous wave generator and the second continuous wave generator are provided, an output of the first continuous wave generator is connected to at least one of a first amplifier, a first mixer, a first filter, and a first attenuator such that the first signal is processed by at least one of the first amplifier, the first mixer, the first filter, and the first attenuator, and wherein an output of the second continuous wave generator is connected to at least one of a second amplifier, a second mixer, a second filter, and a second attenuator such that the second signal is processed by at least one of the second amplifier, the second mixer, the second filter, and the second attenuator.

14. The signal generator according to claim 11, wherein, in case the digital-to analog-converter is provided that generates the first signal and the second signal, an output of the digital-to analog-converter is connected to at least one of an amplifier, a mixer, a filter, and an attenuator such that the first signal and the second signal generated by the digital-to analog-converter are processed by at least one of the amplifier, the mixer, the filter, and the attenuator.

15. The signal generator according to claim 11, wherein, in case the first digital-to-analog converter and the second digital-to-analog converter are provided, an output of the first digital-to-analog converter is connected to at least one of a first amplifier, a first mixer, a first filter, and a first attenuator such that the first signal is processed by at least one of the first amplifier, the first mixer, the first filter, and the first attenuator, and wherein an output of the second digital-to-analog converter is connected to at least one of a second amplifier, a second mixer, a second filter, and a second attenuator such that the second signal is processed by at least one of the second amplifier, the second mixer, the second filter, and the second attenuator.

16. The signal generator according to claim 1, wherein the signal processing circuit is configured to control at least one of an amplifier and an attenuator.

17. The signal generator according to claim 1, wherein the measurement circuit comprises a frequency-selective power meter, or wherein the measurement circuit comprises at least one of a mixer, a filter, an attenuator, and an analog-to-digital converter, or wherein the measurement circuit comprises a comb mixing circuit and an analog-to-digital converter, wherein the comb mixing circuit is configured to mix down the first signal and the second signal as well as the at least one intermodulation product.

18. The signal generator according to claim 1, further comprising a user interface, wherein the signal processing circuit is configured to receive a user input via the user interface, and wherein the signal processing circuit is configured to start or stop controlling the signal generator circuit based on the measurement result.

19. The signal generator according to claim 1, further comprising a user interface, wherein the signal processing circuit is configured to display a measured third-order intercept point on the user interface.

20. The signal generator according to claim 1, further comprising a switchable attenuator provided upstream of the measurement circuit, wherein the signal processing circuit is configured to control the switchable attenuator.
